(19) United States
(12) Patent Application Publication
(10) Pub. No.: US 2012/0205032 A1
(43) Pub. Date: Aug. 16, 2012

(54) MANUFACTURING METHOD OF AIRTIGHT CONTAINER AND IMAGE DISPLAY APPARATUS

(75) Inventor: Mamo Matsumoto, Kawasaki-shi (JP)

(73) Assignee: CANON KABUSHIKI KAISHA, Tokyo (JP)

(21) Appl. No.: 13/357,001

(22) Filed: Jan. 24, 2012

(30) Foreign Application Priority Data
Feb. 10, 2011 (JP) 2011-027339

(51) Int. Cl. C03C 27/10

(52) U.S. Cl. 156/109

(57) ABSTRACT

An airtight container manufacturing method comprises: a step of obtaining an assembled body comprising a pair of glass substrates which is arranged facing each other, and a plurality of frame-like bonding materials each of which is arranged between the pair of the glass substrates; and a step of, by irradiating local heating light to at least a part of the boding materials, melting at least the part of the bonding materials. The melting step includes first step of irradiating the local heating light to the part of the bonding materials so that at least one not-irradiated bonding material is present inside one closed region supposed by linearly linking the irradiated bonding materials, and second step of irradiating the local heating light to the not-irradiated bonding material present inside the one closed region.

### BACKGROUND OF THE INVENTION

1. Field of the Invention

The present invention relates to a manufacturing method of an airtight container and a manufacturing method of an image display apparatus. More particularly, the present invention relates to a method of manufacturing a plurality of airtight containers from a pair of substrates.

2. Description of the Related Art

Conventionally, a technique of forming an internal space having airtightness by bonding glass substrates facing each other has been known. This technique is applied to manufacturing of an airtight container (envelope) to be used in flat panel displays such as an organic light-emitting diode (OLED) display, a field emission display (FED), a plasma display panel (PDP), and the like, and is also applied to manufacturing of a vacuum insulating glass. In case of manufacturing the airtight container like this, a spacing distance defining member and a local adhesive are arranged as necessary between the glass substrates facing each other, a bonding material is arranged to peripheral portions of the glass substrates, and then the glass substrates are bonded to each other by application of heat or the like. Incidentally, as a method of bonding the glass substrates to each other, a whole heating method whereby an assembled body obtained by temporarily assembling the glass substrates is entirely heated (baked) by a furnace, and a local heating method whereby only the peripheral portion of the assembled body is selectively heated by a local heating means have been proposed. Generally, the local heating method is more advantageous than the whole heating method from viewpoints of a time which is required to heat and cool the assembled body, reduction of an energy which is required to heat, and prevention of thermal deterioration of function devices arranged in the container. In case of manufacturing small-scale airtight containers, it is also possible to form, by a pair of glass substrates and a large number of frame-like glass bonding materials inserted between the pair of the glass substrates, a large number of airtight containers each of which has been sealed, and then obtain the individual airtight container by cutting off the glass substrates.

Japanese Patent Application Laid-Open No. 2010-037194 discloses, as a method of simultaneously manufacturing a large number of organic light emitting image display apparatuses, a method of bonding mother glass by melting a plurality of glass bonding materials with use of a laser beam as local heating light. In this method, the bonded mother glass is cut off and separated into individual unit display elements. When the mother glass is bonded by the laser beam, the laser beam is simultaneously irradiated to the plurality of glass bonding materials. Since the laser beam is simultaneously irradiated, a stress deviation applied to the mother glass can be minimized, whereby it is thus possible to suppress that projections on the cut surface, fine fragments and the like occur.

U.S. Patent Application Publication No. 2007/0128965 discloses, as a method of simultaneously manufacturing a large number of airtightly sealed image display apparatuses, a method of bonding mother glass by melting a plurality of glass bonding materials with use of a laser beam as local heating light. To manufacture the image display apparatuses, a laser beam is irradiated in turn to the adjacent bonding materials. Thus, it is possible to improve productivity of the image display apparatuses.

As just described, to manufacture the large number of airtight containers by bonding the glass substrates with use of the local heating light, the method which is not to simply irradiate the local heating light to the bonding materials but is to irradiate simultaneously or in turn the local heating light to the plurality of bonding materials has been known. Consequently, it is possible, by forming the closed space in the method like this, to improve reliability in airtightness of the airtight containers and productivity in manufacture of the airtight containers.

In the conventional manufacturing method of the image display apparatus, the glass bonding material is formed in advance on one of the glass substrates. Then, when the other of the glass substrates is arranged so as to face the one of the glass substrates, the glass bonding material contacts the other of the glass substrates. However, in case of holding the glass bonding material in such a way, a heat transfer quantity from the glass bonging material to the one of the glass substrates at the time when the local heating light is irradiated to the glass bonding material is different from a heat transfer quantity from the glass bonding material to the other of the glass substrates at the time when the local heating light is irradiated to the glass bonding material. Thus, a temperature difference occurs between the pair of the glass substrates. Consequently, a relative movement with friction occurs between the bonding material and the glass substrate due to a thermal expansion difference based on the above temperature difference, whereby there is a possibility that damage of the glass substrate and fine fragments occasionally occur.

Consequently, the present invention aims to provide a manufacturing method of the airtight container, which can reduce the above friction occurred between the glass substrate and the bonding material, and reduce occurrence of the damage of the glass substrate and the fine fragments.

### SUMMARY OF THE INVENTION

A manufacturing method of an airtight container, according to the present invention, comprises: a step of obtaining an assembled body comprising a pair of glass substrates which is arranged facing each other, and a plurality of frame-like bonding materials each of which is arranged between the pair of the glass substrates; and a step of, by irradiating local heating light to at least a part of the boding materials, melting at least the part of the bonding materials. Further, the step of melting the bonding material includes a first irradiating step of irradiating the local heating light to the part of the bonding materials so that at least one bonding material not irradiated by the local heating light is present inside one closed region supposed by linearly linking the bonding materials irradiated by the local heating light, and a second irradiating step of irradiating the local heating light to the bonding material not irradiated by the local heating light being present inside the one closed region.

As a result of the first irradiating step, the one closed region which has been supposed by linearly linking the bonding materials irradiated by the local heating light is obtained. In the closed region, relative displacement of the glass substrates is confined due to cohesiveness (or bonding force) of the bonding material irradiated by the local heating light and then hardened. In such a state, since the local heating light is irradiated to the bonding material not yet irradiated in the closed region, the relative displacement of the glass substrates is confined even if a temperature difference occurs between these glass substrates. Consequently, it becomes difficult for misalignment between the bonding material and the glass substrate and friction due to this misalignment to occur. As a result, it is possible to reduce occurrence of damage of the glass substrate and fine fragments.

Therefore, according to the present invention, it is possible to provide the manufacturing method of the airtight container, which can reduce the occurrence of the friction between the glass substrate and the bonding material, and also reduce the occurrence of the damage of the glass substrate and the fine fragments.

Further features of the present invention will become apparent from the following description of an exemplary embodiment with reference to the accompanying drawings.

### BRIEF DESCRIPTION OF THE DRAWINGS

FIGS. 1A and 1B are respectively a plan view and a cross-section view both illustrating an OLED display to be manufactured by a manufacturing method according to the present invention.

FIG. 2 is a cross-section view for describing in detail a first glass substrate and a light emitting portion.

FIG. 3 is a cross-section view of the glass substrate for describing an example of a process flow according to the present invention.

FIG. 4 is a perspective view for describing a method of irradiating local heating light for each airtight container.

FIGS. 5A and 5B are cross-section views for describing a method of irradiating the local heating light for a plurality of airtight containers.

FIGS. 6A, 6B and 6C are plan views respectively illustrating examples of closed regions obtained in a first irradiating step.

FIGS. 7A and 7B are respectively a plan view and a cross-section view for describing a method of irradiating the local heating light in an example.

### DESCRIPTION OF THE EMBODIMENTS

Hereinafter, an exemplary embodiment of the present invention will now be described in detail with reference to the accompanying drawings. A manufacturing method of an airtight container of the present invention can be applied to a manufacturing method of containers of an FED, an OLED display, a PDP and the like each having a device, which is required to be airtightly (hermetically) sealed from an external atmosphere, in its internal space. Especially, in the image display apparatus such as the OLED display or the like which includes an organic light emitting material being weak in water and oxygen, high airtightness for isolating the inside of the image display apparatus from the outside is required. Here, according to the present invention, it is possible to secure high airtightness on a long-term basis. Incidentally, the manufacturing method of the airtight container according to the present invention is not limited to the manufacturing of the airtight container for use of the above displays. That is, the present invention can be widely applied to manufacturing of an airtight container which has a bonding material in which airtightness is required for the peripheral portions of glass substrates facing each other.

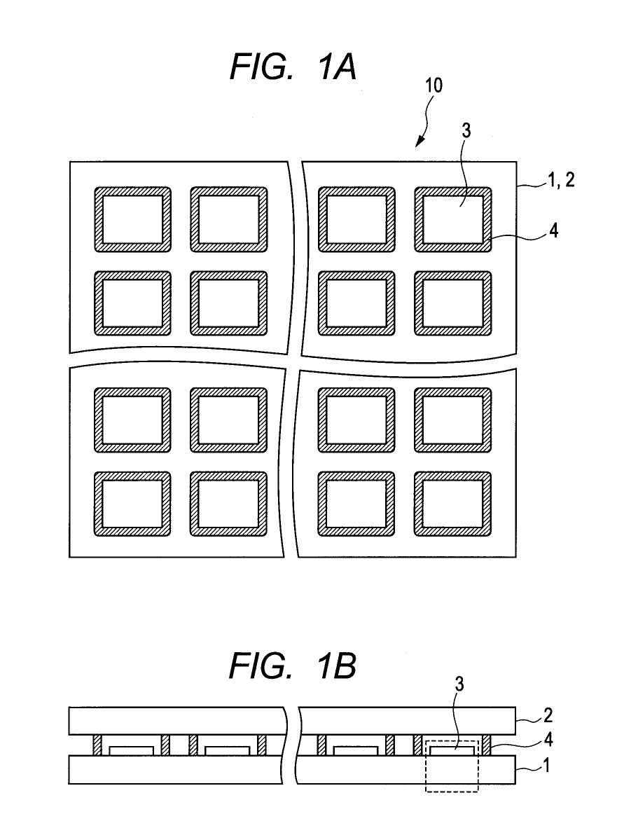

FIGS. 1A and 1B are respectively a plan view and a cross-section view both illustrating the OLED display to be manufactured by the manufacturing method according to the present invention. More specifically, FIG. 1A is the schematic plan view of the display, and FIG. 1B is the schematic cross-section view of the display. As illustrated in FIG. 1B, an OLED display 10 includes a first glass substrate 1, a second substrate 2, and a light emitting unit 3 and a bonding material 4 which are provided between the first glass substrate 1 and the second glass substrate 2. As illustrated in FIGS. 1A and 1B, the plurality of light emitting units 3 are provided on the first glass substrate 1. Moreover, each bonding material 4 is provided so as to surround each light emitting unit 3 thereby sealing the light emitting unit 3 as illustrated in FIG. 1A, and also bonding the first glass substrate 1 and the second glass substrate 2 to each other as illustrated in FIG. 1B.

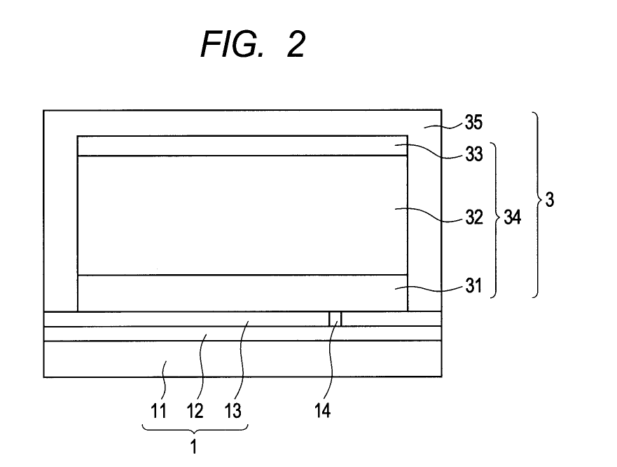

Subsequently, the light emitting unit 3 will be described in detail. FIG. 2 is a partially enlarged cross-section view illustrating the portion indicated by the dotted-line quadrangle in FIG. 1B. The light emitting unit 3 includes an OLED element 34 in which a lower electrode 31, an OLED layer 32 and an upper electrode 33 are laminated in this order, and a protecting layer 35 which covers the upper surface and the side surfaces of the OLED element 34. When a current is applied to the light emitting unit 3, holes injected from an anode (not illustrated) and electrons injected from a cathode (not illustrated) are recombined in a light emitting layer (not illustrated) in the OLED layer 32. Then, the light emitting layer emits red, green and blue lights respectively according to light emitting colors of light emitting materials included in the light emitting layer. Subsequently, the light emitted from the light emitting layer can be fetched from the side of the protecting layer 35.

When the light emitting unit 3 is driven in an active-matrix method, it is a given fact that the first glass substrate 1 is constituted by a substrate 11, a TFT (thin-film transistor) circuit 12 provided on the substrate 11, and a planarizing film 13 provided on the TFT circuit 12. The TFT circuit 12 is electrically connected to the lower electrode 31 through a contact hole 14.

Subsequently, members and materials of constituting the OLED display 10 illustrated in FIGS. 1A and 1B will be described.

Although it is not limited specifically, each of the first glass material 1 and the second glass material 2 can be formed by, for example, a transparent glass material. When the light emitting unit 3 is driven in the active-matrix method, the transparent glass material or the like is used for the first glass substrates 1 and 2.

The lower electrode 31 in the light emitting unit is a reflective electrode for reflecting light emitted from the light emitting layer. The lower electrode 31 is constituted by a metallic material having reflectance of at least 50% or more and preferably 80% or more. As the reflectance becomes high, it becomes possible to improve light fetching efficiency, whereby it is desirable. Although it is not limited specifically, for example, the metallic material having the above reflectance includes a metallic material such as silver, aluminum, chrome, gold, platinum or the like. The lower electrode 31 may be constituted only by a metallic thin film made of the above metallic material. However, if it is difficult only by the metal thin film to inject charges into the OLED layer 32, a transparent electrode layer may be further provided on the metal thin film. Here, a conductive film made by metal oxide is used as the transparent electrode layer. More specifically, a compound film (ITO (Indium Tin Oxide)) made by indium oxide and tin oxide, or a compound film (IZO (Indium Zinc Oxide)) made by indium oxide and zinc oxide is used as the conductive film.

The constitution of the OLED layer 32 constituting a part of the light emitting unit 3 is not limited specifically. For example, a constitution in which a hole injection layer, a hole transport layer, a light emitting layer, an electron transport layer, and an electron injection layer are laminated from the anode side in this order is used.

As a hole injection material constituting the hole injection layer and a hole transport material constituting the hole transport layer, it is desirable to use a material which has hole mobility making injection of the hole from the anode easy and excellent in transport of the injected hole to the light emitting layer. Since the hole injection material and the hole transport material are not limited specifically, various kinds of low-molecular and high-molecular materials can be used. As the low-molecular materials, for example, a triallylamine derivative, a phenylenediamine derivative, a triazole derivate, an oxadiazole derivative, an imidazole derivative, a pyrazoline derivative, and a pyrazolone derivative are used. As other low-molecular materials, for example, an oxazole derivative, a fluorenone derivative, a hydrazone derivative, a stilbene derivative, a phthalocyanine derivative, and a porphyrin derivative are used. Moreover, as the high-molecular materials, for example, polyvinyl carbazole, polysilylene, and polythiophene are used.

As a light emitting material constituting the light emitting layer, a luminescent material and a phosphorescent material which have high light emitting efficiency are used.

An electron transport material constituting the electron transport layer can be arbitrarily selected from materials which have a function for transporting the electron injected from the cathode to the light emitting layer. More specifically, the electron transport material is actually selected in consideration of balance with the hole mobility of the hole transport material, and the like. As the electron transport materials, an oxadiazole derivative, an oxazole derivative, a triazole derivative, a thiadiazole derivative, a pyrazine derivative, a triazole derivative, a triazine derivative, a perylene derivative, a quinoline derivative, and the like are used. Moreover, a quinoxaline derivative, a fluorenone derivative, an anthrone derivative, a phenanthroline derivative, an organometallic complex, and the like are used. However, the electron transport materials are not limited to them.

As an electron injection material constituting the electron injection layer, a material which is obtained by adding, in the above-described electron transport material, alkaline metal, alkaline-earth metal or a compound of alkaline metal and alkaline-earth metal by 0.1% to several tens of % is used. It is possible by adding the alkaline metal or the like to the electron transport material to give electron injection performance.

The upper electrode 33 in the light emitting unit 3 is preferably a material which has transmittance of 80% to 100% so that the light emitted from the light emitting layer can be sufficiently fetched. The material constituting the upper electrode 33 is not limited specifically. For example, a metallic thin film formed to have a film thickness of the extent that light transmits through a metallic material such as silver, aluminum, chrome, gold, platinum or the like, an oxide conductive film such as ITO, IZO or the like, or a laminated body of a thin film formed by the above metallic material and the oxide thin film.

The protection layer 35 constituting a part of the light emitting unit 3 is provided with an aim to prevent the OLED element 34 from directly coming into contact with oxygen, moisture and the like in the atmosphere. The material of the protection layer 35 is not limited specifically, if it is an organic compound having adhesiveness to the OLED element 34. Preferably, a thermosetting resin, a ultraviolet curing resin, or a two-liquid mixing curing resin is used. More specifically, an epoxy resin, an acrylic resin or the like is used. The protection layer 35 may be adhered tightly to the second glass substrate. To improve a moisture-proof property, a metallic nitride film such as silicon nitride, silicon oxynitride or the like, a metallic oxide film such as tantalum oxide or the like, or a diamond thin film may further be provided between the upper electrode 33 and the protection layer 35. Moreover, an absorbent material may be included in the protection layer 35.

When the OLED display 10 is a top-emission display which emits the light generated by the OLED element 34 outwardly from the side of the second glass substrate 2, the protection layer 35 is constituted by a transparent material.

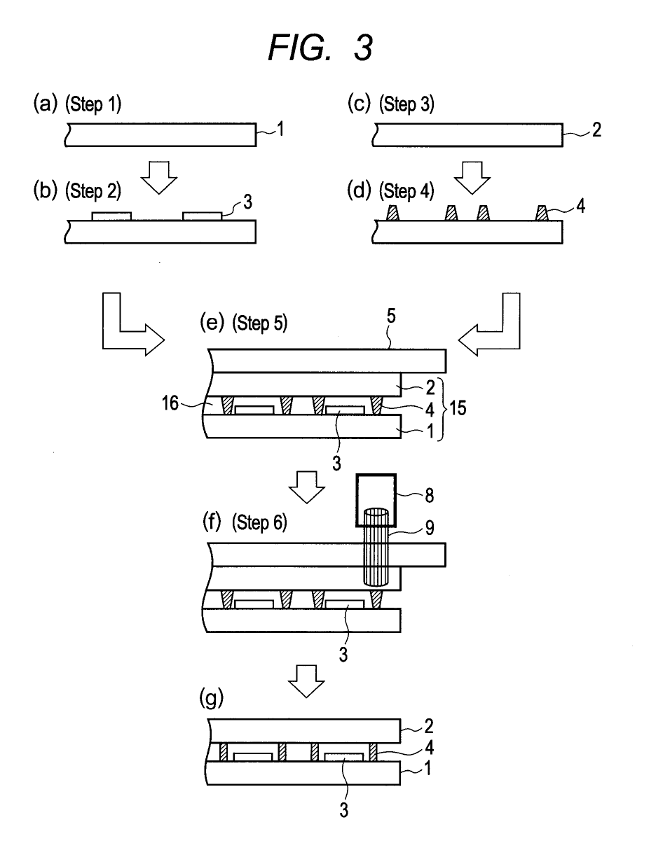

FIG. 3 is a cross-section view of the glass substrate for describing a process flow of concrete processes of manufacturing the airtight container according to the present invention. Hereinafter, the manufacturing method of the airtight container according to the present invention will be described concretely with reference to the process flow indicated in FIG. 3.

(Step 1) Step of Preparing First Glass Substrate ((a) in FIG. 3)

In the manufacturing method of the airtight container according to the present invention, the first glass substrate 1 is first prepared. More specifically, the substrate which is necessary to provide the later-described light emitting unit 3 is prepared. In a case where the OLED display 10 to be manufactured is an active-matrix display apparatus, the TFT circuit 12, the planarizing film 13 and the contact hole 14 all illustrated in FIG. 2 are sequentially provided in this step.

(Step 2) Step of Preparing Light Emitting Unit ((b) in FIG. 3)

Subsequently, the light emitting unit 3 is formed. Here, the lower electrode 31, the OLED layer 32, the upper electrode 33 and the protection layer 35 can be formed in a known method.

(Step 3) Step of Preparing Second Glass Substrate ((c) in FIG. 3)

Subsequently, the second glass substrate 2 is prepared. On the prepared second glass substrate 2, the plurality of frame-like bonding materials 4 are formed in a next step.

(Step 4) Step of Forming Thin Film of Bonding Materials on Second Glass Substrate ((d) in FIG. 3)

Subsequently, the thin film including the bonding materials 4 is formed on the second glass substrate 2. Here, the plurality of bonding materials 4 are formed so that the outermost circumferential bonding materials 4 are arranged along the four sides of a rectangular region. In such a process, glass frit is used as the bonding material 4. A viscosity of the bonding material 4 has a negative temperature coefficient, and a softening point of the bonding material 4 is lower than that of each of the first and second glass substrates 1 and 2. More specifically, an adequate liquid substance is mixed to the glass frit, whereby a frit paste is prepared. Then, the prepared frit paste is applied onto the second glass substrate 2 so as to surround each of the light emitting units 3, whereby the thin film is formed. Incidentally, as a method of applying the frit paste, a dispensing method, a screen printing method, or the like is used. Subsequently, pre-baking is performed to the thin film including the frit paste, whereby the bonding materials 4 are obtained. Here, it is preferable to set the height of the bonding material 4 to 5 μm to 300 μm at the stage of the pre-baking.

(Step 5) Step of Arranging First Glass Substrate and Second Glass Substrate so as to Face Each Other ((e) in FIG. 3)

Subsequently, the first glass substrate 1 and the second glass substrate 2 are arranged so as to face each other. More specifically, the first glass substrate 1 and the second glass substrate 2 are aligned with each other so that each of the light emitting units 3 provided on the first glass substrate 1 is enclosed by the second glass substrate 2 and the corresponding bonding material 4 provided on the second glass substrate 2. Then, the bonding materials 4 are brought into contact with the first glass substrate 1. At this time, to secure the abutting state or the contact state between the bonding materials 4 and the first glass substrate 1, it is desirable to supportively cover the glass substrates 1 and 2 by a glass substrate 5 and thus press the bonding materials 4 to the first glass substrate 1. By doing so, the glass frit is interposed between the first glass substrate 1 and the second glass substrate 2.

In the present embodiment, the bonding materials 4 are formed on the side of the second glass substrate 2. However, a part or the whole of the bonding materials 4 may be formed on the side of the first glass substrate 1. In either case, it is possible to obtain an assembled body 15 in which the pair of the glass substrates 1 and 2 is arranged facing each other and the plurality of frame-like bonding materials 4 each of which is formed on one of the glass substrates and contacts the other of the glass substrates are positioned mutually apart from others in a space 16 interposed between the pair of the glass substrates 1 and 2.

(Step 6) Step of Bonding First Glass Substrate and Second Glass Substrate to Each Other ((f) and (g) in FIG. 3)

Subsequently, local heating light is locally irradiated sequentially to the plurality of bonding materials 4 positioned between the pair of the glass substrates 1 and 2 arranged facing each other, thereby melting the bonding materials 4. Thus, it is possible to bond the first glass substrate 1 and the second glass substrate 2 to each other. Incidentally, a laser beam 9 is preferably used as the local heating light.

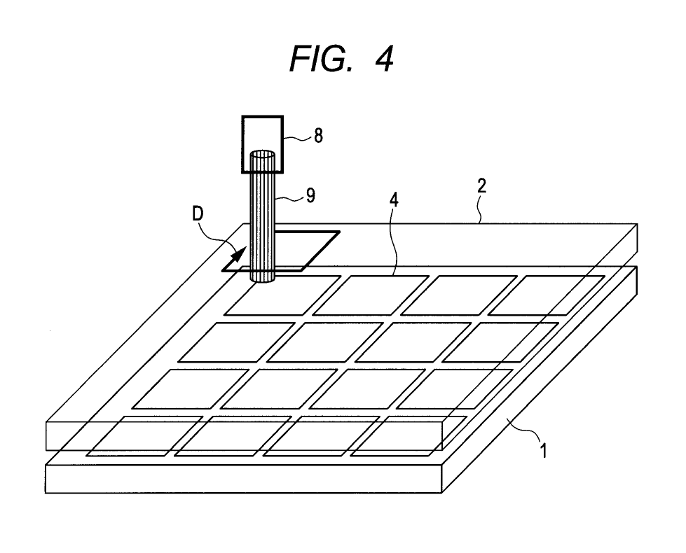

More specifically, as illustrated in FIG. 4, the laser beam 9 generated from a laser head 8 is moved along and irradiated to the plurality of bonding materials 4, thereby bonding the first glass substrate 1 and the second glass substrate 2 arranged facing each other. In the illustrated example, the laser beam 9 is generated from the side of the second glass substrate 2, and then irradiated to the bonding material 4 through the second glass substrate 2. However, the laser beam 9 may be generated from the side of the first glass substrate 1, and then irradiated to the bonding material 4 through the first glass substrate 1. In any case, the laser beam 9 is moved along a frame-shaped direction D in which the bonding material 4 extends, and thus irradiated to the bonding material 4 entirely. The laser beam 9 only has to be able to locally heat the adjacency of the bonding region of the bonding material 4, and a semiconductor laser is preferably used as the light source. More specifically, a semiconductor laser for processing, which has the wavelength in the infrared region, is preferably used from the aspect of performance of locally heating the bonding material 4, transmission performance of the glass substrates 1 and 2, and the like.

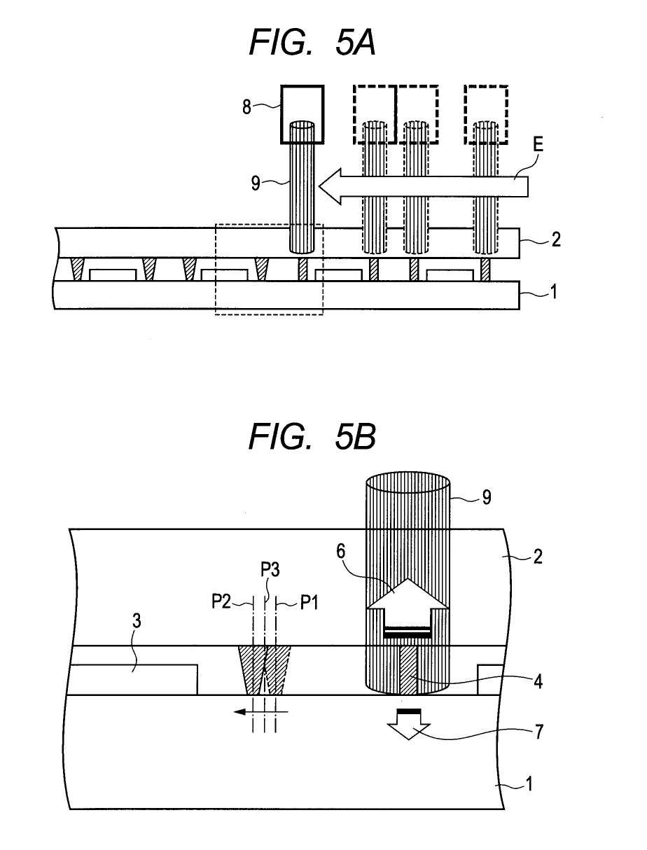

As described above, when the laser beam 9 is transmitted through the second glass substrate 2, the energy of this beam is absorbed by the bonding material 4. Based on this, as illustrated in FIGS. 5A and 5B, the bonding material 4 is heated, and the produced heat is diffused to the first glass substrate 1 and the second glass substrate 2. More specifically, FIG. 5A is the schematic view illustrating the state that the laser beam is irradiated, and FIG. 5B is the enlarged view illustrating the portion indicated by the dotted-line quadrangle in FIG. 5A. The bonding material 4 is formed on the second glass substrate 2, and only contacts the first glass substrate 1. Therefore, diffusion (i.e., a heat transfer quantity) of heat 6 to the second glass substrate 2 is larger than diffusion (i.e., a heat transfer quantity) of heat 7 to the first glass substrate 1, whereby a thermal expansion difference occurs due to a temperature difference between the first glass substrate 1 and the second glass substrate 2. In consequence, when the bonding by the irradiation of the laser beam 9 is sequentially performed in an arbitrary direction E, friction is occurred between the bonding material 4 not yet irradiated by the laser beam and the first glass substrate 1.

For example, when thermal expansion coefficients of the first glass substrate 1 and the second glass substrate 2 are the same, thermal expansion of the second glass substrate 2 is larger than that of the first glass substrate 1 because a temperature of the second glass substrate 2 is higher than that of the first glass substrate 1. For this reason, the position of the bonding material 4 not irradiated by the laser beam is moved from a position P1 to a position P2 (FIG. 5B) in the direction E. On the other hand, since the thermal expansion of the first glass substrate 1 is not larger than that of the second glass substrate 2, the position where the bonding material first contacted the first glass substrate 1 is moved merely from the position P1 to an intermediate position P3 between the positions P1 and P2. Here, since the bonding material 4 only contacts the first glass substrate 1 but is not fixed thereto, the position where the bonding material contacts the first glass substrate 1 is moved finally from the position P3 to the position P2. At that time, since a relative movement with friction occurs between the bonding material 4 and the first glass substrate 1, there is a possibility that the first glass substrate 1 and/or the bonding material 4 are/is damaged and thus fine fragments occur. Moreover, there is a possibility that airtightness of the bonding portion decreases due to the fine fragments.

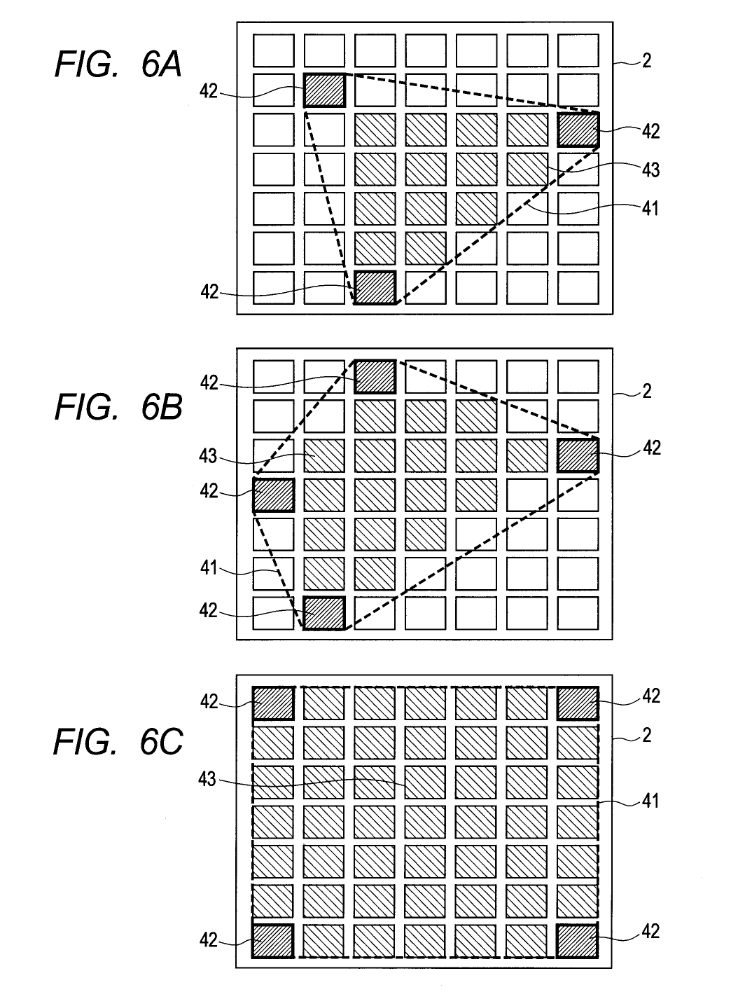

In the manufacturing method according to the present embodiment, the step of melting the bonding material, that is, the step of irradiating the laser beam 9, is divided into two steps, i.e., a first irradiating step and a second irradiating step. In the first irradiating step, as illustrated in FIG. 6A, the local heating light is sequentially irradiated to a specific plurality of bonding materials 42. Here, the specific plurality of bonding materials 42 are selected so that a one closed region 41 is formed when the plurality of bonding materials 42 irradiated by the local heating light are linearly linked each other, and that at least one bonding material 43 not irradiated by the local heating light is present inside the one closed region 41. It should be noted that a range of the one closed region 41 depends on how to link the bonding materials 42, that is, which corners of the adjacent bonding materials 42 should be connected. The one closed region 41 is demarcated by a closed line segment (parts thereof are indicated by the dotted lines) which is drawn to include therein each bonding material 42 irradiated by the local heating light and have a minimum length. For example, this line segment is coincident with a line segment which is obtained by stretching a thread around the outer sides of the respective bonding materials 42 and tensioning the stretched thread. Here, the line connecting the adjacent bonding materials 42 passes through the position as close as possible to the periphery of the region that the bonding materials 4 have been formed.

In the second irradiating step, as illustrated in FIG. 6A, the laser beam 9 is irradiated to the bonding materials 43 not yet irradiated which are included in the region 41 surrounded by the bonding materials 42. Here, since the laser beam has been irradiated to the bonding materials 42, these materials will be also called the already-bonded portions 42. The first glass substrate 1 and the second glass substrate 2 are bonded to each other through the already-bonded portions 42. In the present embodiment as illustrated in FIG. 6A, the laser beam 9 can be irradiated to the 13 bonding materials 43 which are present in the region 41 surrounded by the three already-bonded portions 42. As described above, since the first glass substrate 1 and the second glass substrate 2 have been mutually confined to some extent in the region 41 surrounded by the already-bonded portions 42, it is possible to reduce the friction occurred due to the above-described temperature difference. As a result, it is possible to reduce the damages of the bonding materials 4 and the first glass substrate 1.

As just described, in the present embodiment, the bonding materials 43 to which the laser beam 9 is irradiated are surrounded by the already-bonded portions 42, and the laser beam 9 is irradiated in the state that the first glass substrate 1 and the second glass substrate 2 have been mutually confined. Consequently, it is possible to reduce the damages of the bonding materials 4 and the first glass substrate 1 which occur due to the friction between the bonding materials 4 and the first glass substrate 1.

Incidentally, the positions and the number of the already-bonded portions are not limited to the three already-bonded portions positioned as illustrated in FIG. 6A. That is, as illustrated in FIGS. 6B and 6C, it is more desirable to form the one closed region 41 by the four or more already-bonded portions 42 to confine the first glass substrate 1 and the second glass substrate 2. FIG. 6B shows an example that, in the first irradiating step, the one bonding material 42 is irradiated by the local heating light for each side of the rectangular region in which the bonding materials 4 are arranged. Instead, the two or more bonding materials may be irradiated by the local heating light for the arbitrary side. FIG. 6C shows an example that, in the first irradiating step, only the bonding materials 42 respectively positioned at the four corners of the rectangular region in which the bonding materials are arranged are irradiated by the local heating light. Thus, at least a part of the bonding materials 4 positioned between the pair of the glass substrates 1 and 2 is irradiated by the local heating light. If the number of the already-bonded portions 42 is large, such a confining effect as described above increases. Moreover, if the region 41 is widened, the range by which it is possible to have the confining effect is widened. Then, it is possible to more reinforcing confining force of the first glass substrate 1 and the second glass substrate 2, and it is thus possible to obtain the airtight container have high reliability.

### Example 1

Hereinafter, the main processes in the present invention will be described in more detail by exemplifying a specific example. In the example 1, 49 active-matrix OLED displays (display units) were manufactured by airtightly bonding the first glass substrate and the second glass substrate and cutting out the sections of seven rows and seven columns, by applying the manufacturing method described with reference to FIG. 6C.

### Process 1

### Process of Preparing First Glass Substrate 1, and Forming Bonding Materials 4 on Second Glass Substrate 2

In the first glass substrate 1 and the second glass substrate 2, the glass substrate (AN100: manufactured by Asahi Glass Co., Ltd) having the thickness of 0.7 mm was prepared and cut out to have the external dimensions of 570 mm×500 mm×0.7 mm. Then, the surfaces of the first glass substrate 1 and the second glass substrate 2 were defatted by organic solvent cleaning, pure water rinse and UV-ozone wash.

The TFT circuit 12, the planarizing film 13 and the contact hole 14 illustrated in FIG. 2 were formed on the first glass substrate 1 (one of the glass substrate). Then, the light emitting unit 3 was formed.

In this example, the glass frit was used as the bonging material 4. In the glass frit, the lead-free glass frit of P₂O₅ type (LFP-A50Z: manufactured by Asahi Glass Co., Ltd.) having the thermal expansion coefficient of α=45×10⁻⁷/° C. and the softening point of 348° C. was used as the base material, and the paste to which an organic substance was dispersed and mixed was used as the binder. As illustrated in (d) of FIG. 3, on the second glass substrate 2 (the other of the glass substrate), the paste was formed in the frame shape having the width of 1 mm, the thickness of 20 μm, and the dimensions of 50 mm long×40 mm wide in screen printing. The interval between the adjacent display units was set to 20 mm. After then, the physical object was heated and baked at 460° C. to burn out the organic substance ((a) to (d) of FIG. 3).

### Process 2

### Process of Bringing Bonding Material 4 into Contact with First Glass Substrate 1

Subsequently, the second glass substrate 2 having the bonding materials 4 formed thereon was aligned with the first glass substrate 1, and they were temporarily assembled so that the bonding materials 4 contacted the surface of the first glass substrate 1 having the light emitting units 3 formed thereon. Thus, the plurality of sets each consisting of the light emitting unit and the bonding material surrounding the light emitting unit were formed. After then, the glass substrate 5 (PD200: manufactured by Asahi Glass Co., Ltd.) was secondarily arranged to compensate the welding pressure to the bonding material 4. Moreover, to supplement the pressure force, the first glass substrate 1, the second glass substrate 2 and the bonding material 4 were pressed by the atmospheric pressure with use of a not-illustrated pressure device. By doing so, the first glass substrate 1 was brought into contact with the second glass substrate 2 through the bonding materials 4 ((e) of FIG. 3).

### Process 3

### Process of Irradiating Laser Beam 9 to Bonding Materials 4 at Four Corners of Second Glass Substrate 2

Subsequently, the bonding process using the local heating light, which is the characterizing portion of the present invention, will be described in detail with reference to FIGS. 3, 4 and 6A to 6C.

In the first irradiating step, the local heating light (laser beam 9) was irradiated to the temporarily assembled structure (assembled body 15), formed in the process illustrated in (e) of FIG. 3, including the first glass substrate 1, the second glass substrate 2 and the bonding materials 4. In this example, a one semiconductor laser system for processing was prepared. Here, the optical axis of the laser beam 9 was set to be perpendicular to the glass substrates 1 and 2, and the laser head 8 was arranged so as to have the distance of 8 cm between the laser beam window and the second glass substrate 2 (FIG. 4).

As illustrated in FIG. 6C, the laser beam 9 was irradiated to the bonding material 42 formed at one of the corners of the second glass substrate 2. At this time, the irradiation condition of the laser beam 9 was set to have the wavelength of 980 nm, the laser power of 40 W, and the effective beam diameter of 2.0 mm, and the beam was scanned at the speed of 10 mm/s in the scanning direction D illustrated in FIG. 4. The laser power was defined as the intensity value obtained by integrating all the outgoing beams from the laser head, and the effective beam diameter was defined as the range in which the intensity of the laser beam was e⁻² times or more the beak intensity. During the scanning of the laser beam 9, the physical objects including the bonding materials 4 to be irradiated by the laser beam were fixed, the laser head 8 was moved to the direction D, and the laser beam was irradiated.

The above irradiation was likewise performed to the remaining three corners, and then the first glass substrate 1 and the second glass substrate 2 were bonded to each other.

### Process 4

### Process of Irradiating Laser Beam 9 to Bonding Materials 4 in Region 41

Subsequently, in the second irradiating step, the laser beam 9 was sequentially irradiated to the bonding materials 43, which were formed in the region 41 and not yet irradiated by the laser beam 9. Then, the first glass substrate 1 and the second glass substrate 2 were bonded to each other by all the bonding materials 4. At this time, the set irradiation condition of the laser beam 9 was the same as that in the process 3.

### Process 5

### Process of Cutting First Glass Substrate 1 and Second Glass Substrate 2

After the end of the second irradiating step, the bonded body consisting of the first glass substrate 1 and the second glass substrate 2 were cut along the interspaces between the adjacent bonding materials, whereby the cut-out 49 OLED display units were obtained. More specifically, the cuts were formed at the predetermined positions on both the first glass substrate 1 and the second glass substrate 2 by the glass cutter, and the first glass substrate 1 and the second glass substrate 3 were splited from the cut sides by applying external force. Thus, the individual OLED display units each formed by the set of the one bonding material, the one light emitting unit and the two glass substrates were formed.

When the OLED display formed as above was operated, it was confirmed that image display performance was stably maintained for long time, and the bonded portion secured intensity of an extent applicable to the OLED display and stable airtightness.

### Example 2

In this example, in the first irradiating step, as illustrated in FIG. 6A, the laser beam 9 was irradiated to the bonding materials 42 at the three positions (Process 3 and Process 4). Subsequently, in the second irradiating step, the laser beam 9 was irradiated to the thirteen bonding materials 43 in the region 41 surrounded by the three already-bonded portions 42, and these bonding materials 43 were sequentially bonded. Then, other processes same as those in the example 1 were performed, whereby the OLED displays were formed. When the formed OLED display was operated, it was confirmed that image display performance was stably maintained for long time, and the bonded portion secured intensity of an extent applicable to the OLED display and stable airtightness.

### Example 3

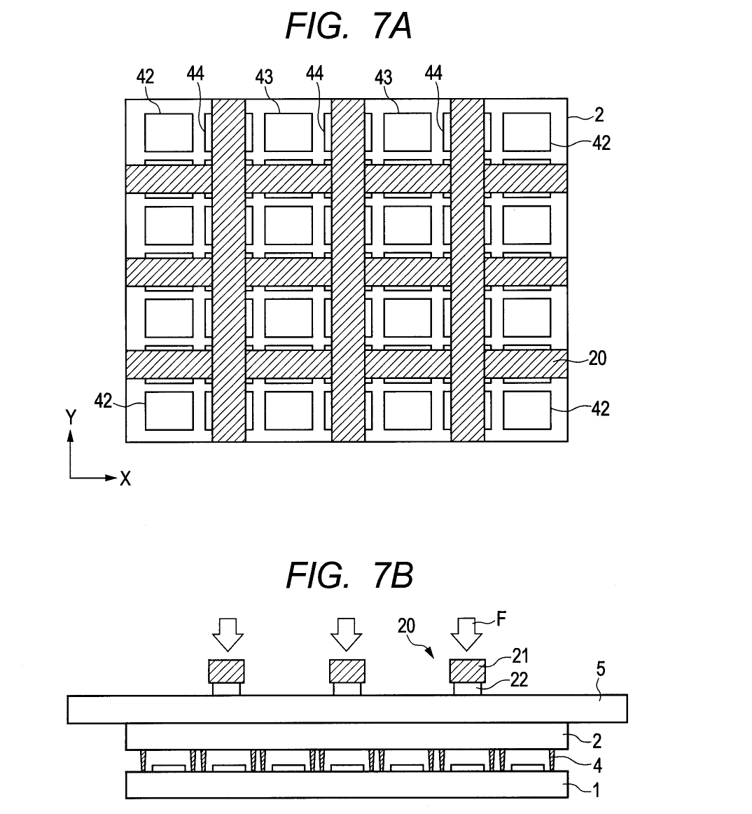

In this example, the processes were the same as those in the example 1 except for use of a pressure device illustrated in FIGS. 7A and 7B in the process 2.

As illustrated in FIG. 7B, a pressure member 20 is arranged above the first glass substrate 1 and the second glass substrate 2 which are bonded to each other by the irradiated laser beam, and is used to press the first glass substrate 1 and the second glass substrate 2 from above. The glass substrate 5 is mounted on the second glass substrate 2 so as to prevent that the pressure member 20 directly contacts the second glass substrate 2. Thus, it is possible to prevent that the second glass substrate 2 is broken or damaged.

The pressure member 20 includes a base 21 and a contact portion 22. The base 21 constitutes the main body of the pressure member 20, and has a weight of a certain extent or more so as to apply an appreciable extent of pressure to the glass substrates. The base 21 is formed by stainless steel (SUS). The contact portion 22 compensates unevenness of the upper portion of the glass substrate 5 which directly contacts the contact portion 22, and prevents that that the glass substrate 5 is broken or damaged. For this reason, the contact portion 22 is formed by a material having predetermined elasticity, for example, a rubber material or an acrylic material.

As illustrated in FIG. 7A, the pressure member 20 has the lattice structure, and its lattice size (i.e., the size of the interval between the adjacent bars constituting the lattice) is set to be larger than the size of each display unit. The pressure member 20 is set so as to press the display units which are adjacent to and surround the display units irradiated by the laser beam 9. In other words, when the laser beam 9 is first irradiated to the four bonding materials 42 respectively arranged at the four corners of the second glass substrate, bonding materials 44 of the three display units adjacent to each of the four bonding materials 42 are pressed by force F. Next, the laser beam 9 is sequentially irradiated to the 12 bonding materials 43 which are not covered by the pressure member 20. After then, the pressure member 20 is moved in a direction X by one unit distance to provide the bonding materials which can be newly irradiated by the laser beam, and the laser beam is sequentially irradiated to the newly provided bonding materials. At this time, the display units which surround the bonding materials irradiated by the laser beam 9 are sequentially pressed. Consecutively, the pressure member 20 is moved in a direction Y by one unit distance, and the laser beam 9 is irradiated to all the bonding materials which are not yet irradiated by the laser beam.

As just described, when the airtight container of the OLED display was manufactured using the pressure member capable of physically pressing the substrates, the adhesive force of the frit increased, and the effect of improving reliability of the OLED display for long time was obtained. When the OLED display manufactured as described above was operated, it was confirmed that image display performance was stably maintained for long time, and the bonded portion secured intensity of an extent applicable to the OLED display and stable airtightness.

While the present invention has been described with reference to the exemplary embodiment, it is to be understood that the invention is not limited to the disclosed embodiment. The scope of the following claims is to be accorded the broadest interpretation so as to encompass all such modifications and equivalent structures and functions.

This application claims the benefit of Japanese Patent Application No. 2011-027339, filed Feb. 10, 2011, which is hereby incorporated by reference herein in its entirety.

What is claimed is:

1. A manufacturing method of an airtight container, comprising:
a step of obtaining an assembled body comprising a pair of glass substrates which is arranged facing each other, and a plurality of frame-like bonding materials each of which is arranged between the pair of the glass substrates; and
a step of, by irradiating local heating light to at least a part of the boding materials, melting at least the part of the bonding materials,
wherein the step of melting the bonding material includes a first irradiating step of irradiating the local heating light to the part of the bonding materials so that at least one bonding material not irradiated by the local heating light is present inside one closed region supposed by linearly linking the bonding materials irradiated by the local heating light, and a second irradiating step of irradiating the local heating light to the bonding material not irradiated by the local heating light being present inside the one closed region.

2. The manufacturing method of the airtight container according to claim 1, wherein
a viscosity of the bonding material has a negative temperature coefficient, and
a softening point of the bonding material is lower than that of the glass substrate.

3. The manufacturing method of the airtight container according to claim 1, wherein
the bonding materials are formed in the space so that the outermost circumferential bonding materials are arranged along four sides of a rectangular region, and
in the first irradiating step, at least the one bonding material is irradiated by the local heating light for each side of the rectangular region.

4. The manufacturing method of the airtight container according to claim 1, wherein
the bonding materials are formed in the space so that the outermost circumferential bonding materials are arranged along four sides of a rectangular region, and
in the first irradiating step, only the bonding materials positioned at four corners of the rectangular region are irradiated by the local heating light.

5. The manufacturing method of the airtight container according to claim 1, wherein the one closed region is demarcated by a closed line segment which is drawn to include therein each bonding material irradiated by the local heating light and have a minimum length.

6. A manufacturing method of an image display apparatus in which the manufacturing method of the airtight container described in claim 1, wherein
the manufacturing method of the image display apparatus comprises a step of forming a plurality of light emitting units on the one of the glass substrates and forming the plurality of bonding materials on the other of the glass substrates,
the step of obtaining the assembled body includes to arrange the pair of the glass substrates facing each other so that the each light emitting unit is surrounded by the each bonding material, and
the manufacturing method of the image display apparatus comprises a step of, after the end of the second irradiating step, cutting off both the glass substrates and thus dividing the glass substrates into a set of the one bonding material and the one light emitting unit.
